(19) United States
(12) Patent Application Publication
(10) Pub. No.: US 2025/0160117 A1
(43) Pub. Date: May 15, 2025

(54) LIGHT EMITTING DIODE AND DISPLAY DEVICE INCLUDING THE SAME

(71) Applicant: Samsung Display Co., LTD., Yongin-si (KR)

(72) Inventors: Seong Jin JEONG, Yongin-si (KR); Ilhoo PARK, Yongin-si (KR); Jin Sook BANG, Yongin-si (KR); Jinouk SONG, Yongin-si (KR); Sang Hoon YIM, Yongin-si (KR); SANGWOOK LEE, Yongin-si (KR)

(73) Assignee: Samsung Display Co., LTD., Yongin-si (KR)

(21) Appl. No.: 18/750,292

(22) Filed: Jun. 21, 2024

(30) Foreign Application Priority Data
Nov. 13, 2023 (KR) 10-2023-0156356

(51) Int. Cl. H10K 50/858; H10K 50/15; H10K 102/00

(52) U.S. Cl. CPC H10K 50/858; H10K 50/156; H10K 2102/311

(57) ABSTRACT

A light emitting element includes a first electrode, a first light emitting unit disposed on the first electrode and including a first light emitting layer, and a second light emitting unit disposed on the first light emitting unit and including a second light emitting layer, the second light emitting unit includes a second hole transport region disposed between the first light emitting unit and the second light emitting layer, and a refractive index n1 of a part of the second hole transport region satisfies the following Equation (1): n2−0.05≤n1≤2.4. In Equation (1), n1 is the refractive index of the portion of the second hole transport region, and n2 is a refractive index of the second light emitting layer.

### CROSS-REFERENCE TO RELATED APPLICATION(S)

This application claims priority to and benefits of Korean Patent Application No. 10-2023-0156356 under 35 U.S.C. § 119, filed on Nov. 13, 2023, in the Korean Intellectual Property Office, the entire contents of which are incorporated herein by reference.

### BACKGROUND

### 1. Technical Field

Embodiments relate to a light emitting element and a display device including the light emitting element, and more specifically, to a light emitting element with increased luminous efficiency and a display device including the light emitting element.

### 2. Description of the Related Art

A light emitting element is a device that converts electrical energy into light energy. Examples of such light emitting elements include organic light emitting elements including organic materials in the light emitting layer, and quantum dot light emitting elements including quantum dots in the light emitting layer.

The light emitting element may include a first electrode and a second electrode that overlap each other, a hole transport region, a light emitting layer, and an electron transport region disposed between the first and second electrodes. Holes injected from the first electrode move to the light emitting layer through the hole transport region, and electrons injected from the second electrode move to the light emitting layer through the electron transport region. The holes and the electrons combine in the light emitting layer area to generate excitons. Light is generated in case that excitons change from an excited state to a ground state.

### SUMMARY

Embodiments provide a light emitting element capable of increasing the light emitting efficiency of the red light emitting element by providing a layer having a selected refractive index between the first light emitting layer and the second light emitting layer.

However, embodiments are not limited to those set forth herein. The above and other embodiments will become more apparent to one of ordinary skill in the art to which the disclosure pertains by referencing the detailed description of the disclosure given below.

A light emitting element according to an embodiment may include a first electrode, a first light emitting unit disposed on the first electrode and including a first light emitting layer, and a second light emitting unit disposed on the first light emitting unit and including a second light emitting layer, wherein the second light emitting unit may include a second hole transport region disposed between the first light emitting unit and the second light emitting layer, and a refractive index n1 of a portion of the second hole transport region may satisfy the following Equation (1).

$$n 2 - 0.05 \leq n 1 \leq 2.4$$

In Equation (1), n1 may be the refractive index of the portion of the second hole transport region, and n2 may be a refractive index of the second light emitting layer.

The second hole transport region may include a second hole transport layer and a second auxiliary layer.

The portion of the second hole transport region may include the second hole transport layer.

The second hole transport layer may have a thickness of about 100 Å or more.

The portion of the second hole transport region may include the second auxiliary layer.

The thickness of the second auxiliary layer may be about 50 Å or more.

The first light emitting layer and the second light emitting layer may emit red light.

The first distance from an upper surface of the first electrode to a lower surface of the first light emitting layer may be about 1000 Å or less.

The first distance may be in a range of about 300 Å to about 500 Å.

The light emitting element may further include a first hole transport region disposed between the first electrode and the first light emitting layer, and a charge generation layer disposed between the first light emitting layer and the second hole transport region.

A display device according to an embodiment may include a substrate, a transistor disposed on the substrate, and a light emitting element electrically connected to the transistor, wherein the light emitting element may include a first electrode, disposed on the first electrode, and a first light emitting unit including one light emitting layer, and a second light emitting unit disposed on the first light emitting unit and including a second light emitting layer, wherein the second light emitting unit may include the first light emitting unit and the second light emitting unit, the second light emitting unit may include a second hole transport region disposed between the light emitting layers, and a refractive index n1 of a portion of the second hole transport region may satisfy the following Equation (1).

$$n 2 - 0.05 \leq n 1 \leq 2.4$$

In Equation (1), n1 may be the refractive index of the portion of the second hole transport region, and n2 may be a refractive index of the second light emitting layer.

The second hole transport region may include a second hole transport layer and a second auxiliary layer.

The portion of the second hole transport region may include the second hole transport layer.

The second hole transport layer may have a thickness of about 100 Å or more.

The portion of the second hole transport region may include the second auxiliary layer.

The thickness of the second auxiliary layer may be about 50 Å or more.

The first light emitting layer and the second light emitting layer may emit red light.

The first distance from an upper surface of the first electrode to a lower surface of the first light emitting layer may be about 1000 Å or less.

The first distance may be in a range of about 300 Å to about 500 Å.

The light emitting element may further include a first hole transport region disposed between the first electrode and the first light emitting layer, and a charge generation layer disposed between the first light emitting layer and the second hole transport region.

According to embodiments, the luminous efficiency of the red light emitting element may be increased by providing a layer having a predetermined refractive index between the first light emitting layer and the second light emitting layer.

### BRIEF DESCRIPTION OF THE DRAWINGS

FIG. 1 is an exploded schematic perspective view of a display device according to an embodiment.

FIG. 2 is a schematic cross-sectional view of a display panel according to an embodiment.

FIG. 3 is a schematic cross-sectional view of a display panel including a light emitting element according to an embodiment.

FIG. 4 is a schematic cross-sectional view of a light emitting element according to an embodiment.

FIG. 5 is a schematic diagram showing a schematic refractive index of a light emitting element according to a comparative example.

FIG. 6 and FIG. 7 are schematic diagrams showing the schematic refractive index of a light emitting element according to an embodiment.

FIG. 8 is a graph showing the luminous efficiency of a red light emitting element according to the refractive index.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

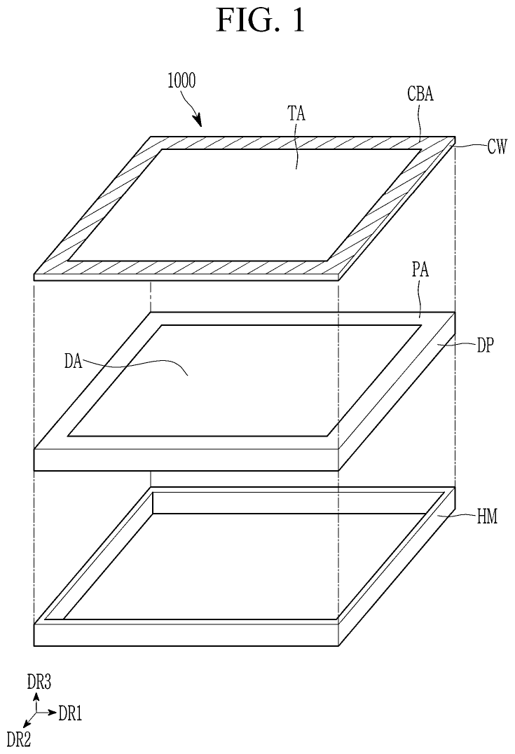

Below, a display device according to an embodiment will be described with reference to FIGS. 1 to 4.

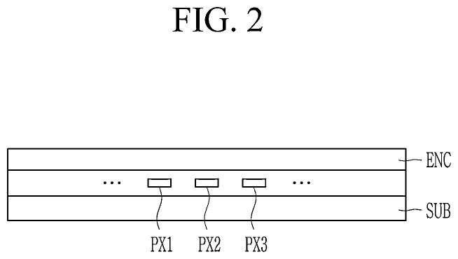

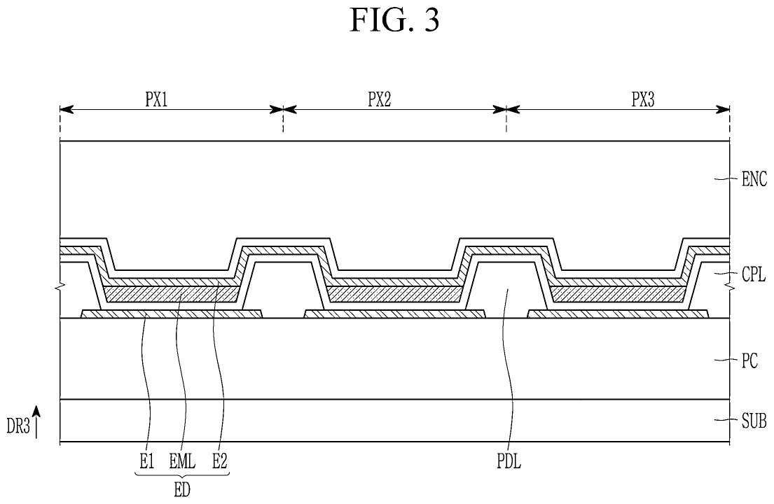

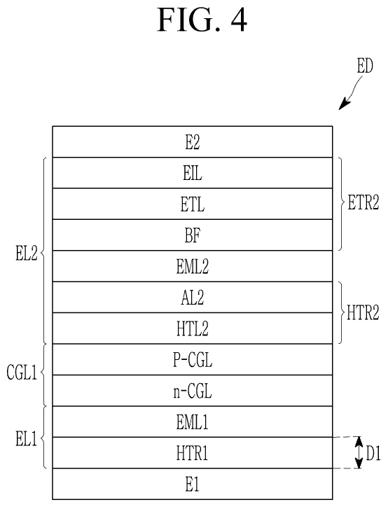

FIG. 1 is an exploded schematic perspective view of a display device according to an embodiment, FIG. 2 is a schematic cross-sectional view of a display panel according to an embodiment, FIG. 3 is a schematic cross-sectional view of a display panel including a light emitting element according to an embodiment, and FIG. 4 is a schematic cross-sectional view of a light emitting element according to an embodiment.

Referring to FIG. 1, a display device 1000 according to an embodiment may include a cover window CW, a display panel DP, and a housing HM.

The cover window CW may include an insulating panel. For example, the cover window CW may be made of glass, plastic, or a combination thereof. The front of the cover window CW may define the front of the display device 1000.

The transmission area TA may be an optically transparent area. For example, the transmission area TA may be an area having visible light transmittance of about 90% or more.

The blocking area CBA may define the shape of the transmission area TA. The blocking area CBA may be adjacent to the transmission area TA and may surround the transmission area TA. The blocking area CBA may be an area with relatively low light transmittance compared to the transmission area TA. The blocking area CBA may include an opaque material that blocks light. The blocking area CBA may have a selected color. The blocking area CBA may be defined by a bezel layer provided (or formed) separately from the transparent substrate defining the transmission area TA, or may be defined by an ink layer formed by inserting or coloring the transparent substrate.

A side of the display panel DP, on which the image is displayed, may be parallel to the side defined by the first direction DR1 and the second direction DR2. The third direction DR3 indicates the normal direction of a side on which the image is displayed, e.g., the thickness direction of the display panel DP. The front (or upper) and back (or lower) surfaces of each member are separated in the third direction DR3. However, the directions indicated by the first to third directions DR1, DR2, and DR3 are relative concepts and may be converted to other directions.

The display panel DP may be a flat rigid display panel, but embodiments are not limited thereto, and may be a flexible display panel. For example, the display panel DP may be made as an organic light emitting display panel. However, the type of the display panel DP is not limited thereto, and the display panel DP may be made as various types of panels. For example, the display panel DP may be made as a liquid crystal display panel, an electrophoretic display panel, an electrowetting display panel, etc. For example, the display panel DP may be made as a next-generation display panel such as a micro light emitting element display panel, a quantum dot light emitting element display panel, or a quantum dot organic light emitting element display panel.

A micro light emitting element (Micro LED) display panel may be made up of light emitting elements having about 10 to about 100 micrometers to form each pixel. These micro light emitting element display panels may have the following advantages. For example, the micro light emitting element display panels may use inorganic materials, the backlight may be omitted, the response speed may be fast, high brightness may be achieved with low power, and the micro light emitting element display panels may not break in case that they are bent. Quantum dot light emitting element display panels may be made by attaching a film including quantum dots or may be formed of a material including quantum dots. Quantum dots may be particles made of inorganic materials such as indium and cadmium, emit light by themselves, and have a diameter of several nanometers or less. By controlling the particle size of quantum dots, light of a selected color may be displayed. The quantum dot organic light emitting element display panel may use a blue organic light emitting element as a light source and may display color by attaching a film including red and green quantum dots thereon or by depositing a material including red and green quantum dots.

The display panel DP according to an embodiment may be made as various other display panels.

As shown in FIG. 1, the display panel DP may include a display area DA where an image is displayed, and a non-display area PA adjacent to the display area DA. The non-display area PA is an area where images are not displayed. For example, the display area DA may have a square shape, and the non-display area PA may have a shape surrounding the display area DA. However, the shape of the display area DA and the non-display area PA may be relatively designed without being limited thereto.

The housing (HM) may provide a predetermined internal space. The display panel DP is mounted inside the housing HM. In addition to the display panel DP, various electronic components, such as a power supply unit, a storage device, and an audio input/output module, may be mounted inside the housing HM.

Next, a display panel according to an embodiment will be described with reference to FIG. 2.

Referring to FIGS. 1 and 2, pixels PX1, PX2, and PX3 may be formed on the substrate SUB corresponding to the display area DA of the display panel DP. Each pixel PX1, PX2, and PX3 may include transistors and a light emitting element connected thereto.

An encapsulation layer ENC may be disposed on the pixels PX1, PX2, and PX3. The display area DA may be protected from external air or moisture through the encapsulation layer ENC. The encapsulation layer ENC may be integrally formed to overlap the entire surface of the display area DA, and may be partially disposed on the non-display area PA.

Hereinafter, a schematic cross-sectional structure of a pixel according to an embodiment will be described with reference to FIGS. 2 and 3.

Referring to FIG. 3, a display panel according to an embodiment may include a substrate SUB. The substrate SUB may include a flexible material such as plastic that may bend, fold, or roll.

A pixel circuit unit PC including a transistor may be disposed on the substrate SUB. For example, the pixel circuit unit PC may include a buffer layer, a semiconductor layer, a gate insulating layer, a gate electrode, an insulating layer, a source electrode, and a drain electrode sequentially arranged on the substrate SUB. The semiconductor layer, gate electrode, source electrode, and drain electrode included in the pixel circuit unit PC may form a transistor.

A light emitting element ED may be disposed on the pixel circuit unit PC. The light emitting element ED may include a first electrode E1, a light emitting layer EML, and a second electrode E2. The light emitting element ED may be electrically connected to a transistor included in the pixel circuit unit PC.

A pixel defining layer PDL may be positioned on the pixel circuit unit PC and the first electrode E1, and the pixel defining layer PDL may have a pixel opening that overlaps the first electrode E1 and defines a light emitting area. The pixel defining layer PDL may include organic materials such as a polyacrylate resin and a polyimide resin, or silica-based inorganic materials.

The pixel opening may have a planar shape substantially similar to that of the first electrode E1, and may have a diamond or octagonal shape similar to a diamond in a plan view, but embodiments are not limited thereto and may have any shape such as a square or polygon. The light emitting layer EML may be disposed on the first electrode E1 overlapping the pixel opening. The light emitting layer EML may be disposed mostly within the pixel opening, and may also be disposed on the side or on the pixel defining layer PDL.

The light emitting layer EML may be made of a low-molecular organic material or a high-molecular organic material such as PEDOT (poly(3,4-ethylenedioxythiophene)). For example, the light emitting layer EML may include a hole injection layer HIL, a hole transporting layer HTL, an electron transporting layer ETL, and an electron injection layer EIL, and the light emitting layer EML may be a multilayer including one or more layers.

The second electrode E2 may be disposed on the light emitting layer EML. The second electrode E2 may be disposed across pixels and may receive a common voltage through a common voltage transmitter in the non-display area.

The first electrode E1, the light emitting layer EML, and the second electrode E2 may form a light emitting element ED. For example, the first electrode E1 may be an anode, which is a hole injection electrode, and the second electrode E2 may be a cathode, which is an electron injection electrode. However, embodiments are not limited thereto, and the first electrode E1 may be a cathode and the second electrode E2 may be an anode according to the driving method of the light emitting display device.

Holes and electrons may be injected into the light emitting layer EML from the first electrode E1 and the second electrode E2, respectively, and light emission occurs in case that the exciton combined with the injected holes and electrons fall from the excited state to the ground state.

A capping layer CPL and an encapsulation layer ENC may be positioned on the second electrode E2. The capping layer CPL and the encapsulation layer ENC may seal the display layer by covering not only the top surface (or upper surface) but also the side surfaces of the display layer including the light emitting element ED.

Since the light emitting element is very vulnerable to moisture and oxygen, the encapsulation layer ENC may seal the display layer and block the inflow (or permeation) of external moisture and oxygen. The encapsulation layer ENC may include a plurality of layers, and may be formed as a composite film including both an inorganic film and an organic film, and may be a triple layer in which a first inorganic film, an organic film, and a second inorganic film are formed sequentially.

Hereinafter, a light emitting element according to an embodiment will be described with reference to FIG. 4.

FIG. 4 is a schematic cross-sectional view of a light emitting element according to an embodiment. The light emitting element ED described in FIG. 4 shows a specific stacked structure of the light emitting element ED included in FIG. 3.

Referring to FIG. 4, the light emitting element ED may include a first electrode E1, a second electrode E2, and two light emitting units EL1 and EL2 disposed between the first electrode E1 and the second electrode E2.

The light emitting element ED according to an embodiment may be a top emitting type. For example, the first electrode E1 may be an anode and the second electrode E2 may be a cathode. The light emitting element ED according to another embodiment may be a bottom emitting type. For example, the first electrode E1 may be a cathode and the second electrode E2 may be an anode.

In an embodiment, the first electrode E1 in the light emitting element ED may be a reflective electrode, and the second electrode E2 may be a transparent or transflective electrode, so the light emitting element ED may emit light from the first electrode E1 in the second electrode E2 direction.

Hereinafter, the case where the light emitting element is a top emitting type will be described.

The first electrode E1 may be formed, for example, by providing a first electrode material on the upper part of the substrate using a deposition method or sputtering method. In case that the first electrode E1 is an anode, the material of the first electrode may be selected from materials having a high work function to facilitate hole injection.

The first electrode E1 may be a reflective electrode, a transflective electrode, or a transmissive electrode. In order to form the first electrode E1, which is a transmissive electrode, the first electrode material may indium tin oxide (ITO), indium zinc oxide (IZO), tin oxide (SnO₂), zinc oxide (ZnO), or any of these, and the first electrode material may be selected from a combination thereof, but embodiments are not limited thereto.

In another example, in order to form the first electrode E1, which is a transflective electrode or a reflective electrode, the first electrode material may be magnesium (Mg), silver (Ag), aluminum (Al), aluminum-lithium (Al—Li), calcium (Ca), magnesium-indium (Mg—In), magnesium-silver (Mg—Ag), and any combination thereof, but embodiments are not limited thereto.

The first electrode E1 may have a single-layer structure or a multi-layer structure having a plurality of layers. For example, the first electrode E1 may have a two-layer structure of ITO/Ag, but embodiments are not limited thereto.

Light emitting units EL1 and EL2 may be disposed on the first electrode E1. The light emitting element ED according to an embodiment may include two light emitting units EL1 and EL2. The light emitting element ED may emit red light.

The light emitting element ED according to an embodiment may include a first hole transport region HTR1, a first light emitting layer EML1, a charge generation layer CGL1, and a second hole transport layer disposed on the first electrode E1, and a second hole transport region HTR2, a second emitting layer EML2, a second electron transport region ETR2, and a second electrode E2. For example, a first electron transport region may be further disposed between the first light emitting layer and the first charge generation layer.

The first hole transport region HTR1 and the second hole transport region HTR2 according to an embodiment may be formed by a general (or typical) method. For example, the first hole transport region HTR1 and the second hole transport region HTR2 may be formed by vacuum deposition, spin coating, casting, a Langmuir-Blodgett (LB) technique, inkjet printing, laser printing, and/or a laser thermoelectric method. The first hole transport region HTR1 and the second hole transport region HTR2 may be formed by various methods such as Laser Induced Thermal Imaging (LITI).

Each of the first hole transport region HTR1 and the second hole transport region HTR2 may include at least one of a hole transport layer, a hole injection layer, and an electron blocking layer, according to an embodiment.

The hole injection layer included in each of the first hole transport region HTR1 and the second hole transport region HTR2 may include a hole injection material. Hole injection materials include phthalocyanine compounds such as copper phthalocyanine, DNTPD (N,N′-diphenyl-N,N′-bis-[4-(phenyl-m-tolyl-amino)-phenyl]-biphenyl-4,4′-diamine), m-MTDATA (4,4′4\″-[Tris(3-methylphenyl)phenylamino] triphenylamine), TDATA (4,4′4\″-Tris(N,N-diphenylamino) triphenylamine), 2-TNATA (4,4′,4\″-Tris {N,-(2-naphthyl)-N-phenylamino}-triphenylamine), PEDOT/PSS (Poly(3,4-ethylenedioxythiophene)/Poly(4-styrenesulfonate)), PANI/DBSA (Polyaniline/Dodecylbenzenesulfonic acid), PANI/CSA (Polyaniline/Camphor sulfonic acid), PANI/PSS (Polyaniline/Poly(4-styrenesulfonate)), NPB (N,N′-di(naphthalene-1-yl)-N,N′-diphenyl-benzidine), NPD (N,N′-Di(1-naphthyl)-N,N′-diphenyl-(1,1′-biphenyl)-4,4′-diamine), polyether ketone including triphenylamine (TPAPEK), 4-Isopropyl-4′-methyldiphenyliodonium [Tetrakis(pentafluorophenyl) borate], HAT-CN (dipyrazino[2,3-f:2′,3′-h] quinoxaline-2,3,6,7,10,11-hexacarbonitrile), etc. may be included.

The hole transport layer independently included in the first hole transport region HTR1 and the second hole transport region HTR2 may include a hole transport material. The hole transport materials may be carbazole derivatives such as N-phenylcarbazole, polyvinyl carbazole, fluorene derivatives, and triphenylamine derivatives such as TPD (N,N′-bis(3-methylphenyl)-N,N′-diphenyl-[1,1-biphenyl]-4,4′-diamine), TCTA (4,4′,4″-Tris(N-carbazolyl) triphenylamine), etc., and may include NPB (N,N′-di(naphthalene-1-yl)-N,N′-diphenyl-benzidine), TAPC (4,4′-Cyclohexylidene bis[N,N-bis(4-methylphenyl)benzenamine]), HMTPD (4,4′-Bis[N,N′-(3-tolyl)amino]-3,3′-dimethylbiphenyl), mCP (1,3-Bis(N-carbazolyl)benzene), CzSi (9-(4-tert-Butylphenyl)-3,6-bis(triphenylsilyl)-9H-carbazole), m-MTDATA (4,4′,4″-[Tris(3-methylphenyl)phenylamino] triphenylamine), and so on.

The first hole transport region HTR1 and the second hole transport region HTR2 may have a thickness of about 100 Å to about 10,000 Å, for example, about 100 Å to about 5,000 Å. For example, the hole injection layer may have a thickness of about 30 Å to about 1000 Å, and the hole transport layer may have a thickness of about 30 Å to about 1000 Å. In case that the thickness of the hole injection layer and the hole transport layer satisfies the range described above, satisfactory hole transport characteristics may be obtained without a substantial increase in driving voltage.

The electron blocking layer may be a layer that prevents electrons from leaking from the electron transport region to the first and second hole transport regions HTR1 and HTR2. The thickness of the electron blocking layer may be from about 10 Å to about 1000 Å. The electron blocking layer is, for example, carbazole-based derivatives such as N-phenylcarbazole and polyvinylcarbazole, fluorene-based derivatives, TPD (N,N′-bis(3-methylphenyl)-N,N′-diphenyl-Triphenylamine derivatives such as [1,1-biphenyl]-4,4′-diamine), TCTA (4,4′,4\″-Tris(N-carbazolyl)triphenylamine), NPD (N,N′-di(naphthalene-1-yl)-N,N′-diphenyl-benzidine), TAPC (4,4′-Cyclohexylidene bis[N,N-bis(4-methylphenyl)benzenamine]), and HMTPD (4,4′-Bis). It may include [N,N′-(3-tolyl)amino]-3,3′-dimethylbiphenyl) or mCP.

The first hole transport region HTR1 and the second hole transport region HTR2 may further include a charge generating material to improve conductivity in addition to the materials mentioned above. The charge generating material may be uniformly or non-uniformly dispersed within the first and second hole transport regions HTR1 and HTR2. The charge generating material may be, for example, a p-dopant. The p-dopant may be one of a quinone derivative, a metal oxide, and a cyano group-including compound, but embodiments are not limited thereto. For example, non-limiting examples of p-dopants include quinone derivatives such as Tetracyanoquinodimethane (TCNQ) and 2,3,5,6-tetrafluoro-7,7′,8,8′-tetracyanoquinodimethane (F4-TCNQ), and metal oxides such as tungsten oxide and molybdenum oxide may be included, but embodiments are not limited thereto.

The second hole transport region HTR2 according to an embodiment may include a second hole transport layer HTL2 including the above-described hole transport material. For example, the second hole transport region HTR2 may further include a second auxiliary layer AL2 disposed between the second hole transport layer HTL2 and the second light emitting layer EML2. The second auxiliary layer AL2 may include a material included in the hole transport region described above, or, according to an embodiment, may include a material that satisfies a refractive index to be described later. A second hole transport layer HTL2 and a second auxiliary layer AL2 may be sequentially disposed between the first light emitting unit EL1 and the second light emitting layer EML2.

The thickness of the second hole transport layer HTL2 may be about 100 Å to about 1000 Å. For example, the second auxiliary layer AL2 may have a thickness of about 50 Å to about 1000 Å. In case that the thickness of the second hole transport layer HTL2 and the second auxiliary layer AL2 satisfies the above range, the luminous efficiency of the light emitting element ED may be improved and the secondary resonance structure may be satisfied. For example, a portion of the second hole transport region HTR2 may have a refractive index that is greater than or equal to the value obtained by subtracting about 0.05 from the refractive index of the second light emitting layer EML2, and smaller than or equal to about 2.4. Specific details will be described later.

The second electron transport region ETR2 may be disposed between the second light emitting layer EML2 and the second electrode E2. For example, the light emitting element ED may further include a first electron transport region disposed between the first light emitting layer EML1 and the charge generation layer CGL1.

Each layer of the second electron transport region ETR2 may be formed by general (or typical) methods. For example, the second electron transport region ETR2 may be formed by vacuum deposition, spin coating, casting, Langmuir-Blodgett (LB), inkjet printing, laser printing, or laser induced thermal imaging (LITI) methods, and the second electron transport region ETR2 may be formed by various methods such as the like.

The second electron transport region ETR2 according to an embodiment may include an electron injection layer EIL, an electron transport layer ETL, and a buffer layer BF, and at least one of these may be omitted. A buffer layer BF, an electron transport layer ETL, and an electron injection layer EIL may be sequentially disposed between the second light emitting layer EML2 and the second electrode E2.

The electron injection layer EIL included in the second electron transport region ETR2 may include an electron injection material. The electron injection material may be a halide metal such as LiF, NaCl, CsF, RbCl, or RbI, a lanthanide metal such as Yb, a metal oxide such as Li₂O or BaO, or LiQ (Lithium quinolate), but embodiments are not limited thereto. The electron injection layer EIL may also be made of a mixture of an electron transport material and an insulating organo metal salt, organic metal salt, and/or organometallic salt. The organic metal salt may be materials with an energy band gap of about 4 cV or more. For example, the organometallic salt may include metal acetate, metal benzoate, metal acetoacetate, metal acetylacetonate, or metal stearate.

The electron transport layer ETL included in the second electron transport region ETR2 may include an electron transport material.

The electron transport material may include a triazine-based compound or an anthracene-based compound. However, embodiments are not limited thereto, and the electronic transport material may include, for example, Alq3(Tris(8-hydroxyquinolinato)aluminum), 1,3,5-tri[(3-pyridyl)-phen-3-yl]benzene, 2,4,6-tris(3′-(pyridin-3-yl) biphenyl-3-yl)-1,3,5-triazine, 2-(4-(N-phenylbenzoimidazolyl-1-ylphenyl)-9,10-dinaphthylanthracene, TPBi(1,3,5-tris(1-phenyl-1H-benzo[d]imidazol-2-yl)benzene), BCP(2,9-Dimethyl-4,7-diphenyl-1,10-phenanthroline), Bphen (4,7-Diphenyl-1,10-phenanthroline), TAZ(3-(4-Biphenylyl)-4-phenyl-5-tert-butylphenyl-1,2,4-triazole), NTAZ(4-(Naphthalen-1-yl)-3,5-diphenyl-4H-1,2,4-triazole), tBu-PBD(2-(4-Biphenylyl)-5-(4-tert-butylphenyl)-1,3,4-oxadiazole), BAlq(Bis(2-methyl-8-quinolinolato-N1,O8)-(1,1′-Biphenyl-4-olato)aluminum), Bebq2(berylliumbis(benzoquinolin-10-olate), ADN(9,10-di(naphthalene-2-yl) anthracene), TSPOI(diphenyl(4-(triphenylsilyl)phenyl)phosphine oxide), TPM-TAZ (2,4,6-Tris(3-(pyrimidin-5-yl)phenyl)-1,3,5-triazine) and mixtures thereof.

The thickness of each electron injection layer EIL may be about 1 Å to about 500 Å, or about 3 Å to about 300 Å. In case that the thickness of the electron injection layer EIL satisfies the range described above, satisfactory electron injection characteristics may be obtained without a substantial increase in driving voltage.

The thickness of each electron transport layer ETL may be about 100 Å to about 1000 Å, for example, about 150 Å to about 500 Å. In case that the thickness of the electron transport layer ETL satisfies the range described above, satisfactory electron transport characteristics may be obtained without a substantial increase in driving voltage.

The second electron transport region ETR2 according to an embodiment may further include a buffer layer BF. The buffer layer BF may prevent holes from leaking from the second hole transport region HTR2 to the second electron transport region ETR2. The thickness of the buffer layer BF may be about 10 Å to about 1000 Å. The buffer layer BF is, for example, BCP (2,9-dimethyl-4,7-diphenyl-1,10-phenanthroline), Bphen (4,7-diphenyl-1,10-phenanthroline), and T2T (2 may include at least one of 4,6-tri ([1,1′-biphenyl]-3-yl)-1,3,5-triazine), but embodiments are not limited thereto.

The first light emitting unit EL1 according to an embodiment may include a first light emitting layer EML1, and the second light emitting unit EL2 may include a second light emitting layer EML2. The first light emitting layer EML1 and the second light emitting layer EML2 may emit red light.

Each light emitting layer EML1 and EML2 may include one or more types selected from organic compounds and semiconductor compounds, but embodiments are not limited thereto. In case that the light emitting layers EML1 and EML2 include an organic compound, the light emitting element ED may be referred to as an organic light emitting element. The organic compound may include a host and a dopant. The semiconductor compound may be a quantum dot. For example, the light emitting element ED may be a quantum dot light emitting element. In another example, the semiconductor compound may be an organic perovskite and/or inorganic perovskite.

The thickness of each light emitting layer EML1 and EML2 may be about 0.1 nm to about 100 nm. For example, the thickness of each light emitting layer EML1 and EML2 may be 15 nm to 50 nm. In case that the above-mentioned range is satisfied, the light emitting element ED may have excellent light emitting characteristics without a substantial increase in driving voltage.

For example, a first distance D1 between a lower surface of the first light emitting layer EML1 and an upper surface of the first electrode E1 according to an embodiment may be about 1000 Å or less, for example, about 300 Å to about 500 Å. Sec, e.g., FIG. 4. In case that the first distance satisfies the above numerical range, each of the first and second light emitting layers EML1 and EML2 may be disposed at the first and second resonance positions.

Each light emitting layer EML1 and EML2 may include a host material and a dopant material. The light emitting layers EML1 and EML2 may be formed by using a phosphorescent or fluorescent material as a dopant in a host material. The light emitting layers EML1 and EML2 may be formed by including a thermally activated delayed fluorescence (TADF) dopant in a host material. In another example, the light emitting layers EML1 and EML2 may include a quantum dot material as a light emitting material. The core of the quantum dot may be selected from group II-VI compounds, group III-V compounds, group IV-VI compounds, group IV elements, group IV compounds, and combinations thereof.

The color of light emitted from the light emitting layers EML1 and EML2 may be determined by the combination of the host material and the dopant material, the type of quantum dot material, and the size of the core.

For example, the host material of the emitting layer EML1 and EML2 may be formed of known materials, and embodiments are not limited thereto. For example, the host material of the emitting layer EML1 and EML2 may include fluoranthene derivatives, pyrene derivatives, arylacetylene derivatives, and anthracene. The host material of the emitting layer EML1 and EML2 may be selected from derivatives, fluorene derivatives, perylene derivatives, chrysene derivatives, etc. Examples may include pyrene derivatives, perylene derivatives, and anthracene derivatives.

For example, the dopant material of the emitting layers EML1 and EML2 may be formed of known materials, but embodiments are not limited thereto. For example, the dopant material of the emitting layers EML1 and EML2 may include styryl derivatives (e.g., 1,4-bis[2-(3-N-ethylcarbazoryl) vinyl] benzene (BCzVB), 4-(di-p-tolylamino)-4′-[(di-p-tolylamino) styryl]stilbene (DPAVB), N-(4-((E)-2-(6-((E)-4-(diphenylamino) styryl) naphthalene-2-yl) vinyl)phenyl)-N-phenylbenzenamine (N-BDAVBi), perylene and its derivatives (e.g., 2,5,8,11-Tetra-t-butylperylene (TBP)), pyrene and its derivatives (e.g., 1,1-dipyrene, 1,4-dipyrenylbenzene, 1,4-Bis(N,N-Diphenylamino) pyrene), N1,N6-di(it may include naphthalen-2-yl)-N1,N6-diphenylpyrene-1,6-diamine), etc.

For example, the refractive index n1 of a portion of the second hole transport region HTR2 according to an embodiment may satisfy the following Equation (1).

$$n 2 - 0.05 \leq n 1 \leq 2.4 \qquad Equation ( 1 )$$

In Equation (1), n1 may be the refractive index of the portion of the second hole transport region HTR2, and n2 may be the refractive index of the second light emitting layer EML2.

For example, the second hole transport region HTR2 may include a second hole transport layer HTL2 and a second auxiliary layer AL2.

Accordingly, the refractive index n1 of the second hole transport layer HTL2 may satisfy the above Equation (1), or the refractive index n1 of the second auxiliary layer AL2 may satisfy the above Equation (1).

The refractive indices of the second hole transport layer HTL2 and the second auxiliary layer AL2 may both satisfy the above Equation (1).

In case that the portion of the second hole transport region HTR2 satisfies the above Equation (1), in the red light emitting element ED in which two light emitting units EL1 and EL2 are stacked, the first light emitting unit EL1 luminous efficiency may be improved. For example, the luminous efficiency of the first light emitting unit EL1 may be greater than that of the second light emitting unit EL2, and through this, the luminous efficiency of the entire light emitting element ED may be improved.

A charge generation layer CGL1 may be disposed between the first light emitting unit EL1 and the second light emitting unit EL2. The charge generation layer CGL1 may include an n-type charge generation layer n-CGL that provides electrons to the light emitting units EL1 and EL2, and a p-type charge generation layer p-CGL that provides holes to the light emitting units EL1 and EL2. For example, according to the embodiment, a buffer layer may be further disposed between the n-type charge generation layer n-CGL and the p-type charge generation layer p-CGL.

The charge generation layer CGL1 may generate charges (e.g., electrons and holes) by forming a complex through an oxidation-reduction reaction in case that a voltage is applied. The charge generation layer CGL1 may provide the generated charges to the adjacent light emitting units EL1 and EL2. The charge generation layer CGL1 may double the current efficiency generated in the light emitting units EL1 and EL2 and may play a role in controlling the balance of charges between adjacent light emitting units EL1 and EL2.

The n-type charge generation layer n-CGL may be disposed adjacent to the first light emitting unit EL1, and the p-type charge generation layer p-CGL may be disposed adjacent to the second light emitting unit EL2.

A second electrode E2 may be disposed on the second light emitting unit EL2. The second electrode E2 may be a cathode, which is an electron injection electrode. The thickness of the second electrode E2 may be about 5 nm to about 20 nm. In case that the above-mentioned range is satisfied, light absorption in the second electrode may be minimized and satisfactory electron injection characteristics may be obtained without a substantial increase in driving voltage.

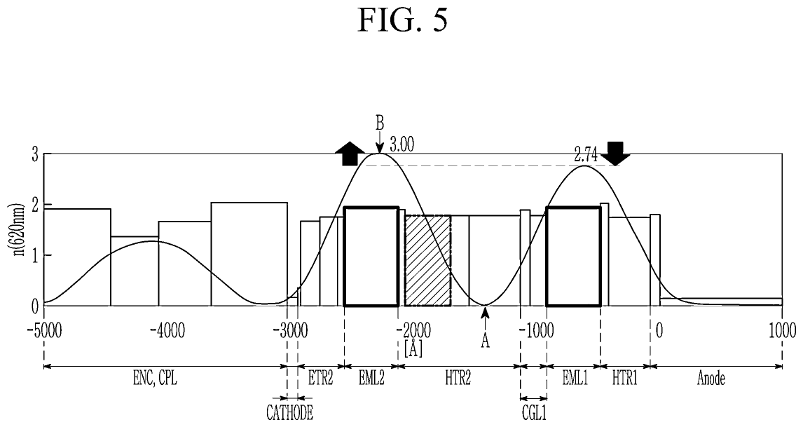

Hereinafter, the refractive index of the hole transport region of the light emitting element according to an embodiment will be described with reference to FIGS. 5 to 8.

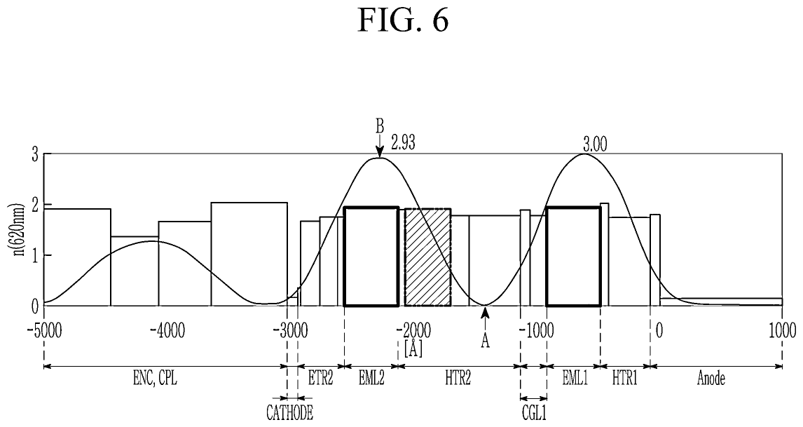

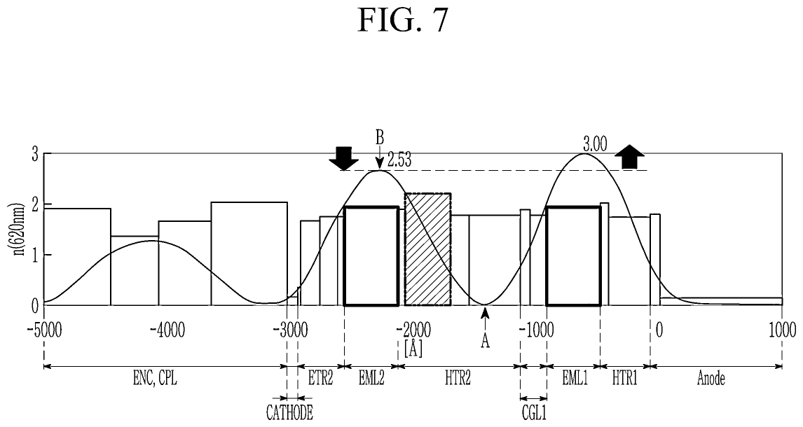

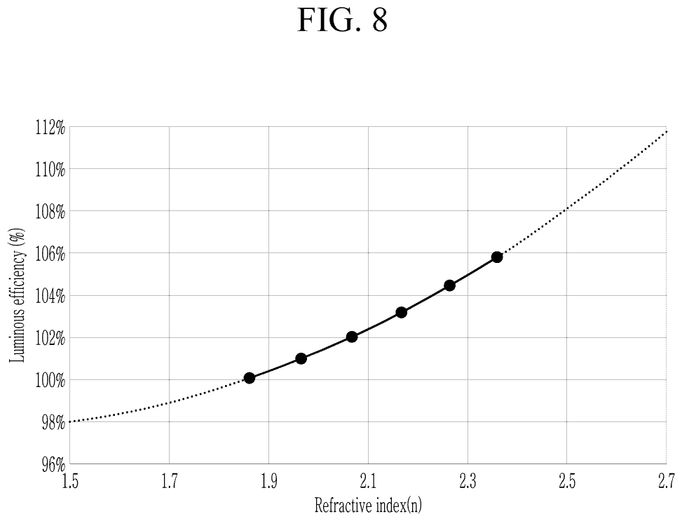

FIG. 5 is a diagram showing a schematic refractive index of a light emitting element according to a comparative example, FIG. 6 and FIG. 7 are diagrams showing a schematic refractive index of a light emitting element according to an example, and FIG. 8 is a graph showing luminous efficiency according to refractive index.

FIG. 5, FIG. 6, and FIG. 7 each show an anode, a first hole transport region, a first light emitting layer, a first charge generation layer, a second hole transport region, a second light emitting layer, a second electron transport region, a cathode, a capping layer, and an encapsulation, this diagram shows the refractive index of each layer in a stacked structure in the order of layers as a bar graph, and shows the luminous efficiency in each layer as a graph curve.

Referring to FIG. 5, in case that a portion of the layer corresponding to the second hole transport region HTR2 (as indicated by a hatched region) has a refractive index that is about 0.21 less than the refractive index of the second emitting layer EML2, the normalized value is A as a reference/standard, the luminous efficiency in the second emitting layer EML2 may increase to about 3, and the luminous efficiency in the first light emitting layer EML1 decreases to about 2.74.

Referring to FIG. 6, a portion of the layer included in the second hole transport region HTR2 (as indicated by a hatched region) may have a refractive index that is about 0.04 less than the refractive index of the second emitting layer EML2.

For example, the luminous efficiency of the second emitting layer EML2 may decrease to the normalized value of about 2.93, and the luminous efficiency of the first light emitting layer EML1 may increase to about 3. The luminous efficiency of the first light emitting layer EML1 may increase.

Also, referring to FIG. 7, a portion of the layer included in the second hole transport region HTR2 (as indicated by a hatched region) may have a refractive index that is about 0.16 greater than that of the second emitting layer EML2. For example, the luminous efficiency of the second emitting layer EML2 may decrease to the normalized value of about 2.53, and the luminous efficiency of the first light emitting layer EML1 may increase to about 3. The luminous efficiency of the first light emitting layer EML1 may increase.

In FIG. 6 and FIG. 7, it was confirmed that the luminous efficiency in the first light emitting layer EML1 increases in case that the portion of the layer (e.g., hole transport layer or auxiliary layer) included in the second hole transport region HTR2 has a predetermined refractive index, and through this, it was confirmed that the luminous efficiency of the entire light emitting element could be increased. For example, the portion of the above-described second hole transport region HTR2 may be disposed between positions A and B based on the luminous efficiency graph.

However, in the case of the comparative example of FIG. 5, the refractive index of the layer included in the second hole transport region is not within the refractive index range according to an embodiment, and it was confirmed that the luminous efficiency in the first light emitting layer was significantly reduced.

For example, as shown in FIG. 8, in case that the refractive index of a portion of the layer included in the second hole transport region increases from about 1.8 to about 2.4, the luminous efficiency of the light emitting element that emits red light may increase to about 100. It was confirmed that the percentage increased from about 100% to about 106%. However, for example, it may be seen that in case that the difference between the refractive index of the portion of the layer included in the second hole transport region and the second light emitting layer is large as shown in FIG. 5, the luminous efficiency may be reduced.

As the refractive index of a part of the hole transport region adjacent to the second light emitting layer increases, the increase in light emitting efficiency of the first light emitting layer corresponding to the primary resonance position may be greater than the decrease in light emitting efficiency of the second light emitting layer corresponding to the secondary resonance position. Accordingly, the overall luminous efficiency of the red light emitting element in which two light emitting units are stacked may increase.

According to an embodiment, the luminous efficiency of a red light emitting element in which two light emitting units are stacked may be increased by making the refractive index of a portion of the second hole transport region slightly smaller or larger than the refractive index of the second light emitting layer.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A light emitting element, comprising:
a first electrode;
a first light emitting unit disposed on the first electrode and including a first light emitting layer; and
a second light emitting unit disposed on the first light emitting unit and including a second light emitting layer, wherein
the second light emitting unit includes a second hole transport region disposed between the first light emitting unit and the second light emitting layer, and
a refractive index n1 of a portion of the second hole transport region satisfies a following Equation (1):
$$n 2 - 0.05 \leq n 1 \leq 2.4 ,$$
wherein, in Equation (1), n1 is the refractive index of the portion of the second hole transport region, and n2 is a refractive index of the second light emitting layer.

2. The light emitting element of claim 1, wherein
the second hole transport region comprises a second hole transport layer and a second auxiliary layer.

3. The light emitting element of claim 2, wherein
the portion of the second hole transport region includes the second hole transport layer.

4. The light emitting element of claim 3, wherein
the second hole transport layer has a thickness of about 100 Å or more.

5. The light emitting element of claim 2, wherein
the portion of the second hole transport region includes the second auxiliary layer.

6. The light emitting element of claim 5, wherein
the second auxiliary layer has a thickness of about 50 Å or more.

7. The light emitting element of claim 1, wherein
the first light emitting layer and the second light emitting layer emit red light.

8. The light emitting element of claim 1, wherein
a first distance from an upper surface of the first electrode to a lower surface of the first light emitting layer is about 1000 Å or less.

9. The light emitting element of claim 8, wherein
the first distance is in a range of about 300 Å to about 500 Å.

10. The light emitting element of claim 1, wherein
the light emitting element further comprises:
a first hole transport region disposed between the first electrode and the first light emitting layer; and
a charge generation layer disposed between the first light emitting layer and the second hole transport region.

11. A display device, comprising:
a substrate;
a transistor disposed on the substrate; and
a light emitting element electrically connected to the transistor, wherein
the light emitting element comprises:
a first electrode;
a first light emitting unit disposed on the first electrode and including a first light emitting layer and
a second light emitting unit disposed on the first light emitting unit and including a second light emitting layer;
the second light emitting unit includes a second hole transport region disposed between the first light emitting unit and the second light emitting layer, and
a refractive index n1 of a portion of the second hole transport region satisfies a following Equation (1):
$$n 2 - 0.05 \leq n 1 \leq 2.4 ,$$
wherein, in Equation (1), n1 is the refractive index of the portion of the second hole transport region, and n2 is a refractive index of the second light emitting layer.

12. The display device of claim 11, wherein
the second hole transport region includes a second hole transport layer and a second auxiliary layer.

13. The display device of claim 12, wherein
the portion of the second hole transport region includes the second hole transport layer.

14. The display device of claim 13, wherein
the second hole transport layer has a thickness of about 100 Å or more.

15. The display device of claim 12, wherein
the portion of the second hole transport region includes the second auxiliary layer.

16. The display device of claim 15, wherein
the second auxiliary layer has a thickness of about 50 Å or more.

17. The display device of claim 11, wherein
the first light emitting layer and the second light emitting layer emit red light.

18. The display device of claim 11, wherein
a first distance from an upper surface of the first electrode to a lower surface of the first light emitting layer is about 1000 Å or less.

19. The display device of claim 18, wherein
the first distance is in a range of about 300 Å to about 500 Å.

20. The display device of claim 11, wherein
the light emitting element further comprises:
a first hole transport region disposed between the first electrode and the first light emitting layer, and
a charge generation layer disposed between the first light emitting layer and the second hole transport region.
